(19) United States
(12) Patent Application Publication
(10) Pub. No.: US 2023/0307442 A1
(43) Pub. Date: Sep. 28, 2023

(54) INTEGRATED CIRCUIT CAPACITOR

(71) Applicant: TEXAS INSTRUMENTS INCORPORATED, Dallas, TX (US)

(72) Inventors: Mark James Taylor, Scarborough, ME (US); Matthew Charles Araujo, Scarborough, ME (US)

(21) Appl. No.: 18/072,702

(22) Filed: Jan. 31, 2023

Related U.S. Application Data
(60) Provisional application No. 63/323,616, filed on Mar. 25, 2022.

(51) Int. Cl. H01L 27/06; H01L 21/762

(52) U.S. Cl. CPC H01L 27/0629; H01L 21/76224; H01L 28/60

(57) ABSTRACT

Described examples include an integrated circuit having a transistor that has a transistor well extending into a semiconductor substrate having a first dopant concentration; a gate electrode over the transistor well; and a gate insulating layer between the transistor well and the gate electrode, the gate insulating layer having a first thickness. The integrated circuit also has a capacitor that has a capacitor well extending into the substrate having a second dopant concentration greater than the first dopant concentration; a capacitor electrode over the capacitor well; and a homogeneous capacitor insulating layer between the capacitor well and the capacitor electrode having a greater thickness than the gate insulating layer.

### CROSS-REFERENCE TO RELATED APPLICATIONS

This application claims the benefit under 35 U.S.C. § 119(e) to co-owned U.S. Provisional Patent Application Ser. No. 63/323,616, filed Mar. 25, 2022, entitled “Robust Silicon-on-Insulator gate oxide capacitor,” which is hereby incorporated by reference in its entirety herein.

### TECHNICAL FIELD

This relates generally to capacitors, and more particularly to improved integrated circuit capacitors.

### BACKGROUND

Metal contamination can cause several problems with semiconductor devices. With regard to capacitors, many capacitors include one plate that is a diffusion in the substrate, another plate that is a conductive layer above the substrate with a dielectric layer separating the two plates. Metal from furnace walls and other semiconductor fabrication devices can contaminate the crystalline silicon substrate. Great effort is expended by production engineers to minimize this contamination, but it cannot be completely eliminated. During fabrication steps and, in some cases, during use of the semiconductor device, some of this metal contamination may migrate to the dielectric/semiconductor interface and may enter the dielectric. This can alter the characteristics of the dielectric so that the capacitor does not operate as designed and, in some cases, may cause a short between the capacitor plates. Therefore, it is desirable to provide a capacitor configuration that mitigates the effects of such metal contamination.

### SUMMARY

In accordance with an example, an integrated circuit includes a transistor having: a transistor well extending into a semiconductor substrate having a first dopant concentration; a gate electrode over the transistor well; and a gate insulating layer between the transistor well and the gate electrode, the gate insulating layer having a first thickness. The integrated circuit also includes a capacitor having: a capacitor well extending into the substrate having a second dopant concentration greater than the first dopant concentration; a capacitor electrode over the capacitor well; and a homogeneous capacitor insulating layer between the capacitor well and the capacitor electrode having a greater thickness than the gate insulating layer.

In accordance with another example, an integrated circuit includes a substrate having a buried insulating layer proximate to but not extending to a surface of the substrate; an epitaxial layer on the surface of the substrate having a first conductivity type; and a buried layer in the epitaxial layer extending to the buried insulating layer having a second conductivity type opposite the first conductivity type. The integrated circuit also includes a capacitor having: a capacitor well having the first conductivity type and a dopant concentration of at least 4×10¹⁸ atoms/cm³ in the epitaxial layer extending to the surface of the epitaxial layer but not extending to the buried layer; a capacitor insulating layer having the surface of the epitaxial layer on the capacitor well; a capacitor plate on the capacitor insulating layer; and a contact region having the first conductivity type in the capacitor well.

In accordance with another example, a method includes forming a buried insulating layer proximate to but not extending to a surface of a substrate having a first conductivity type and implanting a transistor buried layer in a transistor area of the substrate and a capacitor buried layer in a capacitor area of the substrate, the transistor buried layer and the capacitor buried layer extending to the buried insulating layer and having a second conductivity type opposite the first conductivity type. The method also includes epitaxially depositing an epitaxial layer on the surface of the substrate having the first conductivity type and forming a sinker layer having the second conductivity type extending from the transistor buried layer to a surface of the epitaxial layer in the transistor area. The method also includes forming a capacitor well in the capacitor area having the first conductivity type in the epitaxial layer extending to the surface of the epitaxial layer but not extending to the capacitor buried layer and a first oxidizing of a surface of the epitaxial layer in the transistor area and the capacitor area. The method also includes removing oxide formed on the capacitor area formed by the first oxidizing and a second oxidizing of a surface of the epitaxial layer in the transistor area and the capacitor area. The method also includes depositing and patterning a conductive layer on an oxide formed by the second oxidizing, the conductive layer serving as a gate in the transistor area and a capacitor plate in the capacitor area and introducing dopant of the first conductivity type into the surface of the epitaxial layer not covered by the gate in the transistor area and the capacitor plate in the capacitor area, the dopant serving as a first source/drain region and a second source/drain region in the transistor area, the first source/drain region and the second source/drain region formed in the sinker layer on opposing sides of the gate, and the dopant serving as a contact region formed in the capacitor well.

### BRIEF DESCRIPTION OF THE DRAWINGS

FIG. 1 is a side view of an example capacitor.

FIG. 2 is a side view of another example capacitor.

FIGS. 3A-3K (collectively “FIG. 3”) are side views illustrating an example process for fabricating a capacitor.

FIGS. 4A-4J (collectively “FIG. 4”) are side views of an example process for fabricating capacitor.

FIGS. 5A-5J (collectively “FIG. 5”) are side views of an example process for forming a transistor.

### DETAILED DESCRIPTION

In the drawings, corresponding numerals and symbols generally refer to corresponding parts unless otherwise indicated. The drawings are not necessarily drawn to scale.

In this description, the terms “on” and “over” may include layers or other elements where intervening or additional elements are between an element and the element that it is “on” or “over.”

Various disclosed devices and methods of the present disclosure may be beneficially applied to integrated circuits by providing different thermal oxide thicknesses in different devices in a single oxidation process. While such examples may be expected to simplify manufacturing and reduce undesirable contamination that may otherwise occur in multiple thermal oxidation steps, no particular result is a requirement of the present invention unless explicitly recited in a particular claim.

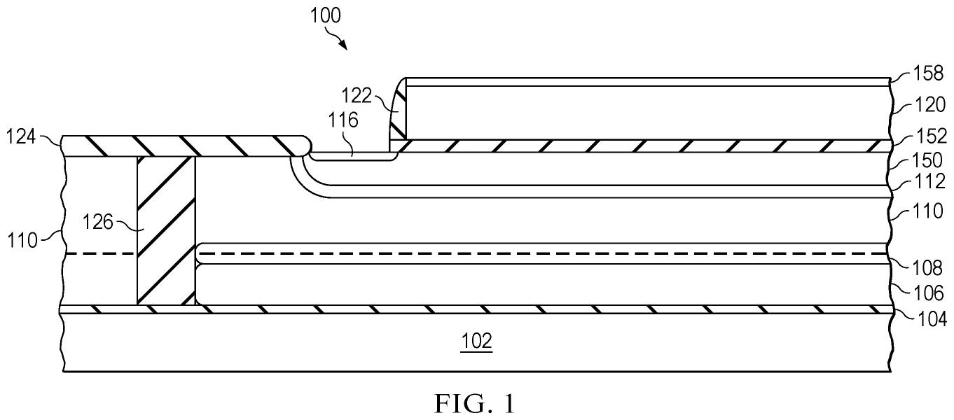

FIG. 1 is a side view of an example capacitor 100 formed in a capacitor area of an integrated circuit. A buried insulating layer such as buried oxide layer 104 is formed in substrate 102 by implantation of oxygen into substrate 102. Capacitor buried layers such as first buried layer 106 and second buried layer 108 are formed by implantation of dopant ions into the substrate 102. In this example, substrate 102 is a semiconductor substrate. In an example, the dopant ions are antimony, arsenic, and/or phosphorus. In an example, first buried layer 106 and second buried layer 108 have a dopant density of approximately 1×10¹⁹ atoms/cm³, within a range of 2×10¹⁸ to 2×10¹⁹. Epitaxial layer 110 is then formed by epitaxial deposition. In an example, N-type epitaxial layer 110 is in-situ doped to a concentration of about 3×10¹⁸ atoms/cm³ (lightly doped, or N—) during the epitaxial deposition process by including dopant bearing gas during the process. As shown in FIG. 1, a portion of second buried layer 108 will diffuse into epitaxial layer 110 during the epitaxial deposition process.

Trench isolation 126 is formed by etching a trench from the surface of epitaxial layer 110 to buried oxide layer 104. An oxide layer (not shown) is formed on the surface of the trench by either deposition or thermal oxidation. As an alternative, other dielectric materials may be used on the walls of the trench. The remainder of trench isolation 126 is then filled with polycrystalline silicon. Although trench isolation 126 is only shown in one place in FIG. 1, in most examples, trench isolation 126 surrounds the area in which capacitor 100 is formed. Field oxide 124 also surrounds capacitor 100. Field oxide is formed by local oxidation of the surface of epitaxial layer 110 or by formation of shallow trenches that are subsequently filled with deposited silicon dioxide or another suitable dielectric.

Using a photoresist mask, first plate region 112 (sometimes referred to as a capacitor well) and second plate region 150 are formed by implantation of dopant ions. The edge of second plate region 150 proximate to trench isolation 126 is spaced 2 to 4 μm from trench isolation 126 in this example. In an example, the dopant ions are arsenic and/or phosphorus. The dopant level of second plate region 150 is selected to provide good conductivity throughout the plate. An example dopant concentration of second plate region is 5×10¹⁸ atoms/cm³, within a range of 5×10¹⁷ to 1×10¹⁹ atoms/cm³. The conductivity of first plate region 112 is lower. In an example, first plate region 112 has a dopant density of approximately 2×10¹⁷ atoms/cm³, within a range of 5×10¹⁵ to 2×10¹⁷ atoms/cm³. First plate region 112 provides a gradual doping profile that helps avoid high localized fields that may cause punch through failures. In addition, to lower the number of dislocations in epitaxial layer 110, first plate region 112 does not extend to second buried layer 108. This provides a portion of epitaxial layer 110 that has not been implanted, thus avoiding the crystal dislocations caused by implantation. Avoiding dislocations caused by implantation provides fewer pathways for migration of metals and other contaminants from the bulk of substrate 102 and/or epitaxial layer 110 to the interface of gate oxide layer 152 and second plate region 150, thus mitigating the chance of failure caused by these metals and other contaminants.

Gate oxide layer 152 (sometimes called a gate insulating layer) is formed by thermal oxidation on the surface of epitaxial layer 110 that is not covered by field oxide 124. Polycrystalline silicon is deposited overall using a deposition process such as chemical vapor deposition that includes a dopant material for conductivity of polycrystalline silicon plate 120. The top portion of polycrystalline silicon plate 120 is then doped to form contact area 158. Polycrystalline silicon plate 120 is then patterned to form a gate electrode or capacitor electrode as shown in FIG. 1.

A side wall 122 is optionally formed by deposition of a dielectric and then anisotropically etching away the dielectric leaving the side wall 122. Contact 116 (sometimes called a contact region) is then formed by implantation of dopant ions of the same conductivity as second plate region 150. In an alternative configuration, contact 116 and contact area 158 may be silicide regions formed by reacting a metal, such as titanium, tungsten, and cobalt, with the silicon of second plate region 150 and polycrystalline silicon plate 120, respectively. Although some processing steps are included in the explanation of the components of capacitor 100, they are included only to more clearly explain the structure involved and do not in any way limit the structures of capacitor 100 nor does it limit the methods by which those structures may be created.

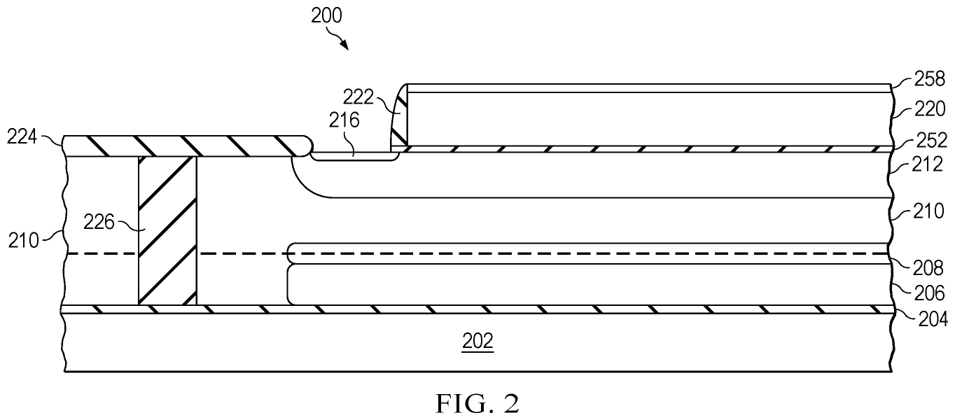

FIG. 2 is a side view of another example capacitor 200 formed in a capacitor area of an integrated circuit. Capacitor 200 is structured for a lower operating voltage than capacitor 100. For example, capacitor 100 may be utilized in a 7 V circuit and capacitor 200 may be utilized in a 5 V circuit. A buried insulating layer such as buried oxide layer 204 is formed in substrate 202 by implantation of oxygen into substrate 202. First buried layer 206 and second buried layer 208 are formed by implantation of dopant ions into the substrate 202. In an example, first buried layer 206 and second buried layer 208 have a dopant density of approximately 1×10¹⁹ atoms/cm³, within a range of 2×10¹⁸ to 2×10¹⁹ atoms/cm³. A difference between first buried layer 206 and first buried layer 106 (FIG. 1), and between second buried layer 208 and second buried layer 108 (FIG. 1) is that first buried layer 206 and second buried layer 208 are separated from trench isolation 226 by a distance in the range of 0.3 to 1.5 μm. In this example, they are separated by 0.7 μm. In the higher voltage device, it is more important to avoid electric field concentrations at the corners of first buried layer 106 and second buried layer 108 (FIG. 1). In the lower voltage device, it is more important to avoid stray capacitances involving first buried layer 206 and second buried layer 208. In an example, the dopant ions are antimony, arsenic, and/or phosphorus.

Epitaxial layer 210 is then formed by epitaxial deposition. In an example, epitaxial layer 210 is lightly doped to an N— doping during the epitaxial deposition process by including dopant bearing gas during the process. As shown in FIG. 2, a portion of second buried layer 208 will diffuse into epitaxial layer 210 during the epitaxial deposition process. Trench isolation 226 is formed by etching a trench from the surface of epitaxial layer 210 to buried oxide layer 204. An oxide layer (not shown) is formed on the surface of the trench by either deposition or thermal oxidation. As an alternative, other dielectric materials may be used on the walls of the trench. The remainder of trench isolation 226 is then filled with polycrystalline silicon. Although trench isolation 226 is only shown in one place in FIG. 2, in most examples, trench isolation 226 surrounds the area in which capacitor 200 is formed. Field oxide 224 also surrounds capacitor 200. Field oxide is formed by local oxidation of the surface of epitaxial layer 210 or by formation of shallow trenches that are subsequently filled with deposited silicon dioxide or another suitable dielectric.

Using a photoresist mask, plate region 212 (sometimes referred to as a capacitor well) is formed by implantation of dopant ions. In an example, the dopant ions are arsenic and/or phosphorus. In an example, plate region 212 has a dopant density of approximately 2×10¹⁷ atoms/cm³, within a range of 5×10¹⁵ to 2×10¹⁷ atoms/cm³. A second plate region such as first plate region 112 (FIG. 1) is not needed because of the lower operating voltage of capacitor 200. In addition, to lower the number of dislocations in epitaxial layer 210, plate region 212 does not extend to second buried layer 208. This provides a portion of epitaxial layer 210 that has not been implanted, thus avoiding the crystal dislocations caused by implantation. Avoiding dislocations caused by implantation provides fewer pathways for migration of metals and other contaminants from the bulk of substrate 202 and/or epitaxial layer 210 to the interface of gate oxide layer 252 and plate region 212, thus mitigating the chance of failure caused by these metals and other contaminants.

Gate oxide layer 252 is a homogeneous layer of silicon dioxide that is formed by a single thermal oxidation on portion of the surface of epitaxial layer 210 that is not covered by field oxide 224. Polycrystalline silicon plate 220 is deposited overall using a deposition process such as chemical vapor deposition that includes a dopant material for conductivity of polycrystalline silicon plate 220. The top portion of polycrystalline silicon plate 220 is then doped to form contact area 258. Polycrystalline silicon plate 220 is then patterned to form a gate electrode as shown in FIG. 2.

A side wall 222 is optionally formed by deposition of a dielectric and then anisotropically etching away the dielectric leaving the side wall 222. Contact 216 is then formed by implantation of dopant ions of the same conductivity as plate region 212. In an alternative configuration, contact 216 and contact area 258 may be silicide regions formed by reacting a metal, such as titanium, tungsten, and cobalt, with the silicon of plate region 212 and polycrystalline silicon plate 220, respectively. Although some processing steps are included in the explanation of the components of capacitor 200, they are included only to more clearly explain the structure involved and do not in any way limit the structures of capacitor 200 nor does it limit the methods by which those structures may be created.

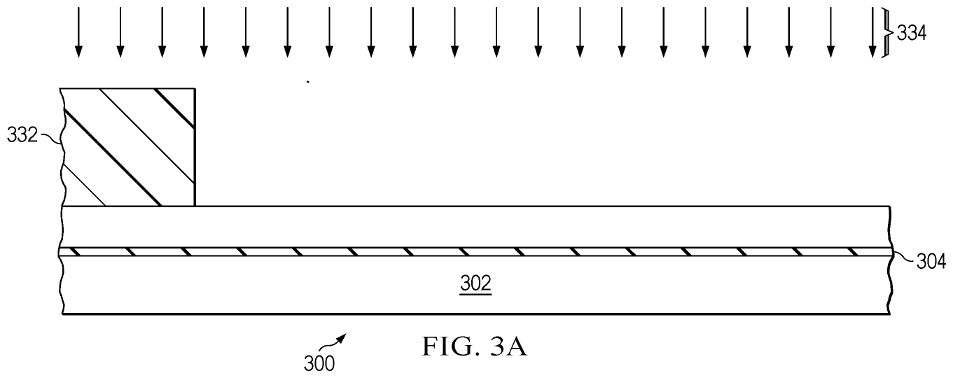

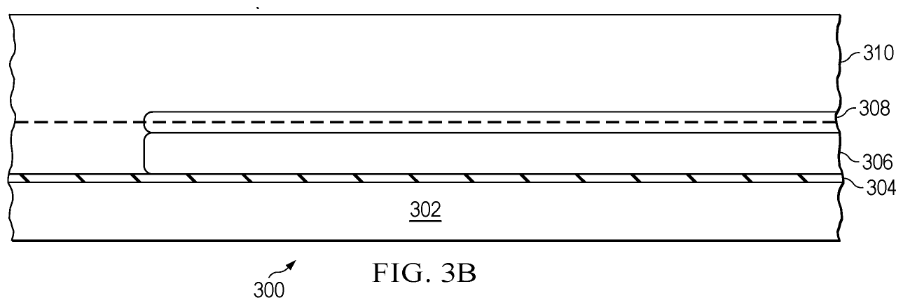

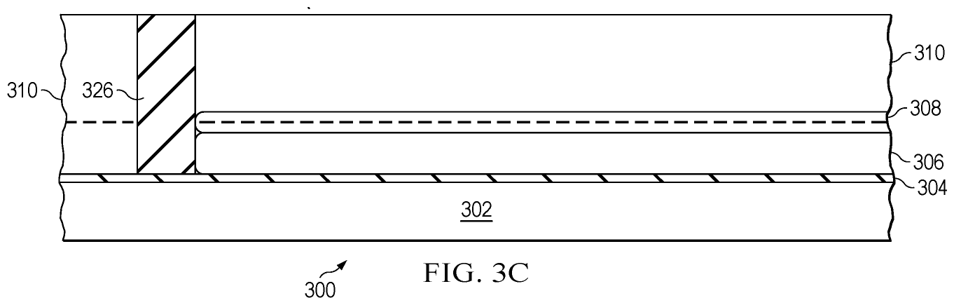

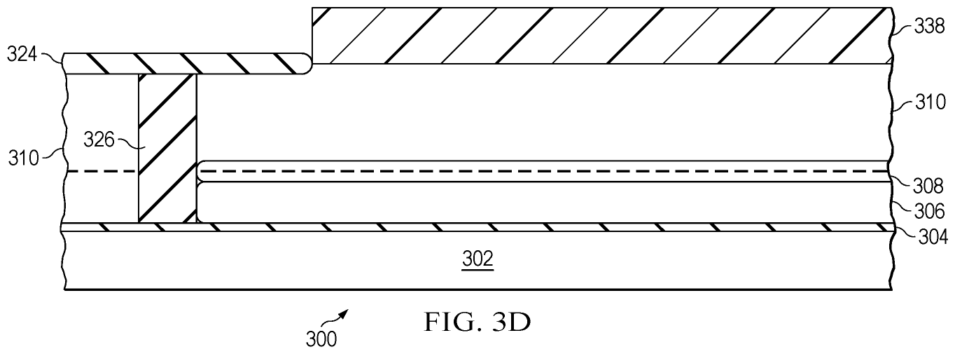

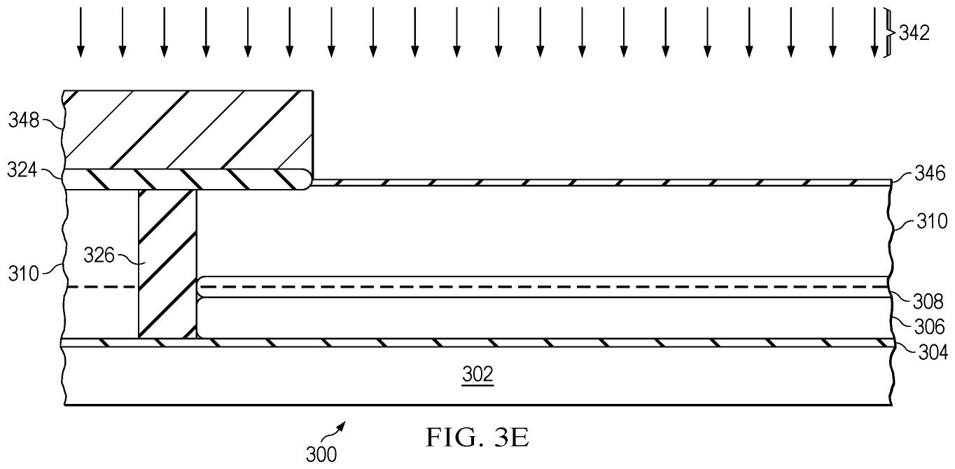

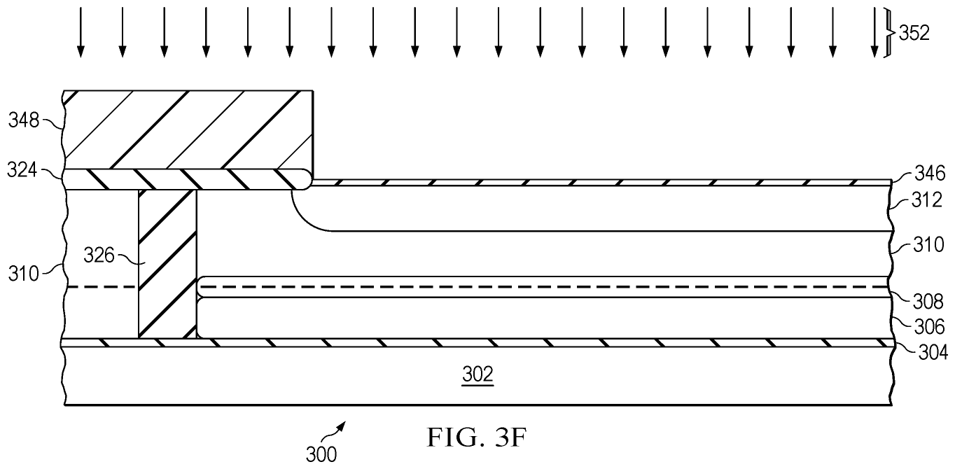

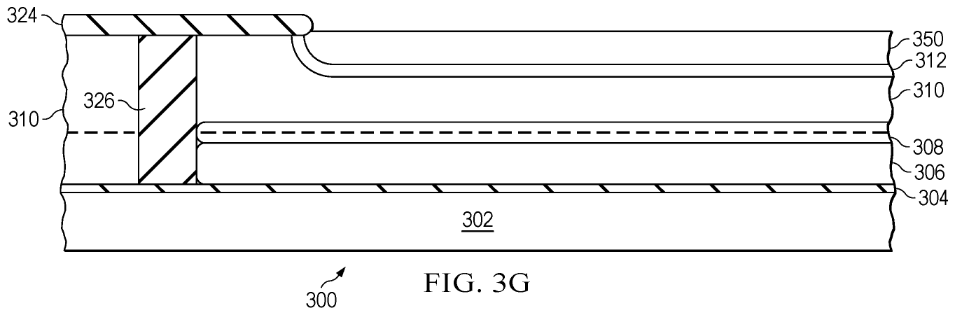

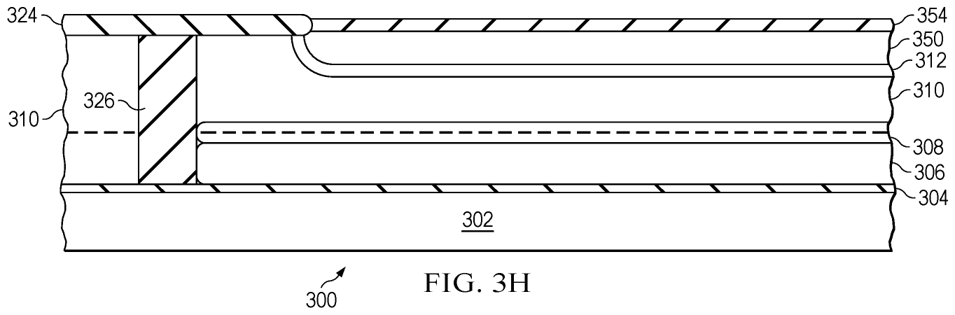

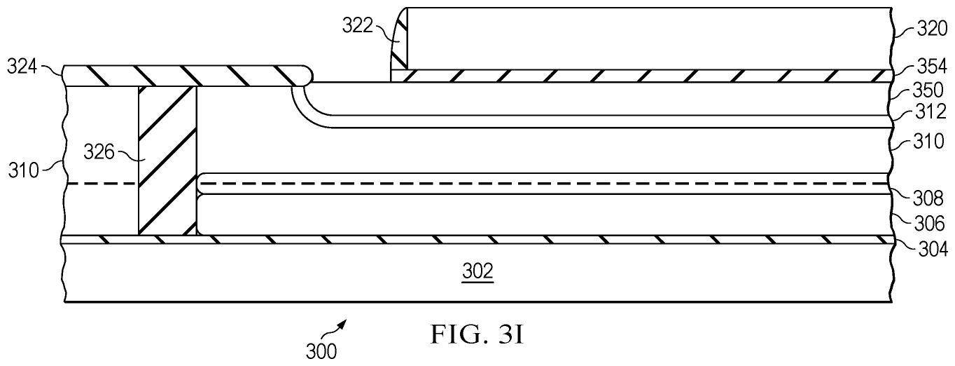

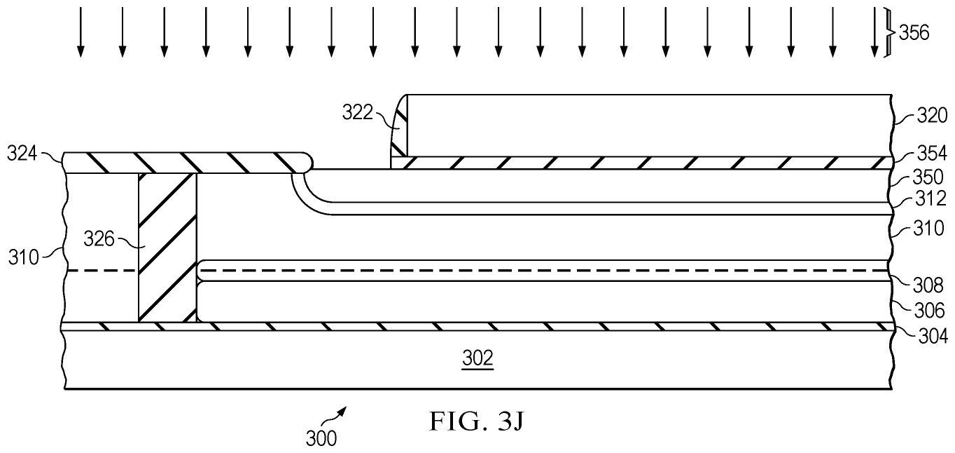

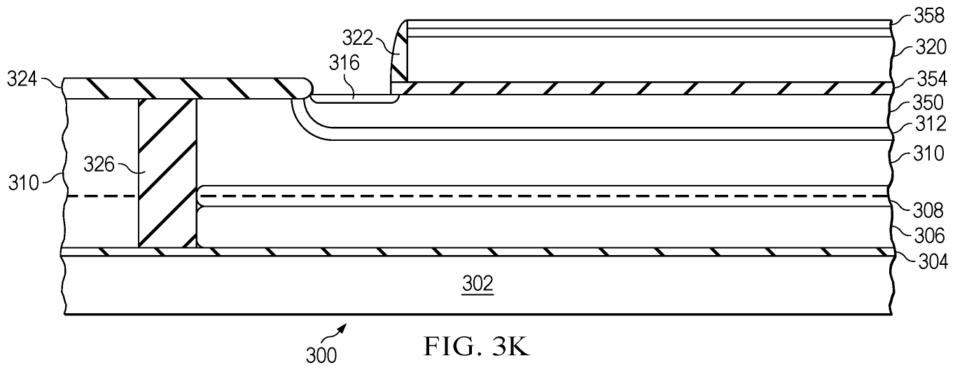

FIGS. 3A-3K (collectively “FIG. 3”) are side views illustrating an example process for fabricating a capacitor 300 consistent with the capacitor 100 (FIG. 1). Buried oxide layer 304 is formed in substrate 302 by implantation of oxygen into substrate 302. In this example, substrate 302 is lightly doped N-type. Photoresist mask 332 is formed and patterned for the formation of buried layers. A first ion implantation 334 includes a two-step implantation. A first step is implantation of antimony ions having a density of 1×10¹⁵ atoms/cm² at an energy of 140 keV using first mask 432. The second step is implantation of phosphorous ions having a density of 1.28×10¹³ and an energy of 90 keV. After annealing and formation of epitaxial layer 310 as shown in FIG. 3B, the first step forms first buried layer 306 and the second step forms second buried layer 308. Epitaxial deposition forms epitaxial layer 310 to a thickness of 2 μm. In an example, epitaxial layer 310 is lightly doped to an N— doping during the epitaxial deposition process by including dopant bearing gas during the process. As shown in FIG. 3B, a portion of second buried layer 308 will diffuse into epitaxial layer 310 during the epitaxial deposition process.

Trench isolation 326 is formed as shown in FIG. 3C. A masked etch forms a trench from the surface of epitaxial layer 310 to buried oxide layer 304, which serves as an etch stop. In this example, thermal oxidation forms a thin oxide layer (not shown) on the surface of the trench. As an alternative, other dielectric materials may be used on the walls of the trench, such as deposited silicon nitride. Chemical vapor deposition (CVD) fills the remainder of the trench with polycrystalline silicon. A planarizing process such as chemical mechanical polishing (CMP) removes the portion of the deposited polycrystalline silicon outside of the trench. Although trench isolation 326 is only shown in one place in FIG. 3, in most examples, trench isolation 326 surrounds the area in which capacitor 300 is formed. Field oxide 324 also surrounds capacitor 300. Field oxide 324 is formed by local oxidation of the surface of epitaxial layer 310 using a second mask 338, as shown in FIG. 3D, or by formation of shallow trenches that are subsequently filled with deposited silicon dioxide or another suitable dielectric.

As shown in FIG. 3E, second mask 338 is then removed. A sacrificial oxide layer 346 is formed on the exposed portions of epitaxial layer 310 using an N₂/O₂ ambient at a temperature of 1,270° C. for 15 minutes to a thickness of about 600 Å as shown in FIG. 3E. Using third mask 348, second implant 342 implants phosphorus ions having a density of 7.25×10¹⁴ ion/cm² and an energy of 130 keV to form first plate region 312 (sometimes referred to as a capacitor well). Third implant 352 is a chain of implants of phosphorus ions having densities of 1.1×10¹³ ion/cm², 4.1×10¹¹ ion/cm², and 1.9×10¹² ion/cm², and energies of 360 keV, 190 keV, and 80 keV, respectively, to form second plate region 350 as shown in FIG. 3G. The dopant level of second plate region 350 is selected to provide good conductivity throughout the plate. The conductivity of first plate region 312 is lower. First plate region 312 provides a gradual doping profile that helps avoid high localized fields that may cause punch-through failures. The edge of first plate region 312 proximate to trench isolation 326 is spaced 2 to 4 μm from trench isolation 326 in this example. In addition, to lower the number of dislocations in epitaxial layer 310, first plate region 312 does not extend to second buried layer 308 and does not include a sinker layer coupling first plate region 312 and second plate region 350 to buried layer 308. This provides a portion of epitaxial layer 310 that has not been implanted, thus avoiding the crystal dislocations caused by implantation. Avoiding dislocations caused by implantation provides fewer pathways form migration of metals and other contaminants from the bulk of substrate 302 and/or epitaxial layer 310 to the surface of second plate region 350 where the interface with the gate oxide will be, thus mitigating the chance of failure caused by these metals and other contaminants. Sacrificial oxide layer 346 is then removed using plasma etching or wet etching.

Capacitor oxide layer 354 (sometimes called a gate insulating layer) is formed by thermal oxidation in a steam ambient at a temperature of 850° C. for 110 minutes, which forms capacitor oxide layer 354 on the surface of epitaxial layer 310 that is not covered by field oxide 324 as shown in FIG. 3H. Capacitor oxide layer 354 is about 170 Å (17 nm) thick in this example. The growth rate of the capacitor oxide layer 354 is determined in part by the dopant concentration in the second plate region 350. In particular, because the dopant concentration in the second plate region 350 is high relative to the dopant concentration in the first plate region 312, the capacitor oxide layer 354 generally has a greater growth rate than it would in the absence of the second plate region 350, e.g. if the oxide layer were grown directly on the first plate region 312. This aspect is addressed further in the discussion below.

As shown in FIG. 3I, polycrystalline silicon plate 320 is deposited overall using a deposition process such as chemical vapor deposition that includes a dopant material for conductivity of polycrystalline silicon plate 320. The top portion of polycrystalline silicon plate 320 is then doped by implantation to form contact area 358. Polycrystalline silicon plate 320 is then patterned as shown in FIG. 3J. A side wall 322 is optionally formed by deposition of a dielectric that is then anisotropically etched away leaving side wall 322. This anisotropic etching also removes the exposed portions of capacitor oxide layer 354. Implantation 356 then forms contact 316 by implanting arsenic with a density of 2.53×10¹⁵ ions/cm², and an energy of 100 keV as shown in FIG. 3K. In an alternative configuration, contact 316 and contact area 358 may be silicide regions formed by reacting a metal, such as titanium, tungsten, and cobalt, with the silicon of second plate region 350 and polycrystalline silicon plate 320, respectively.

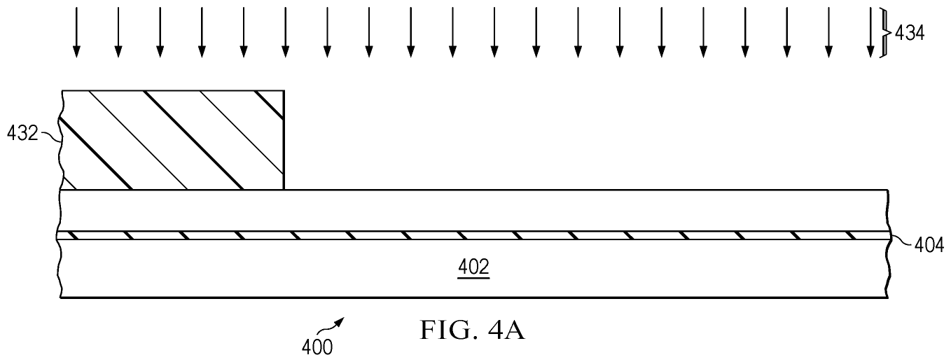

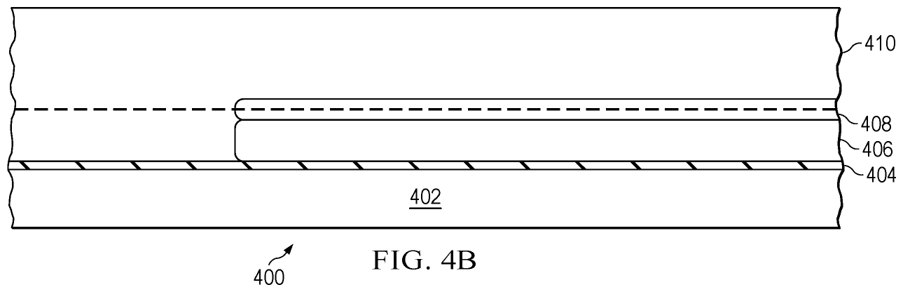

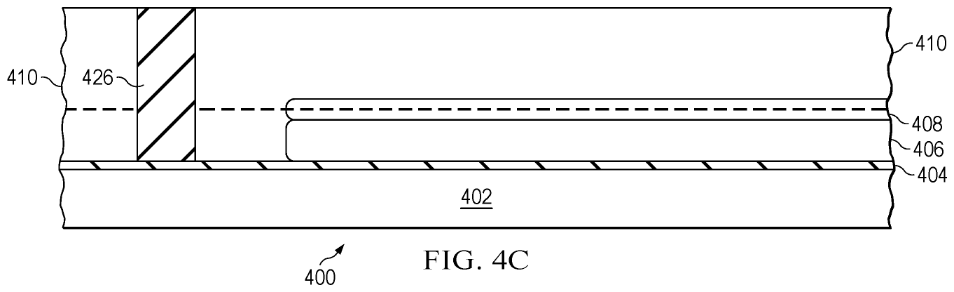

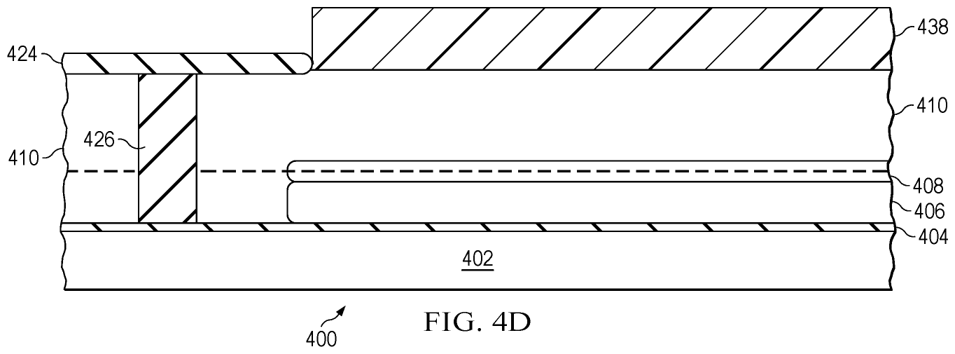

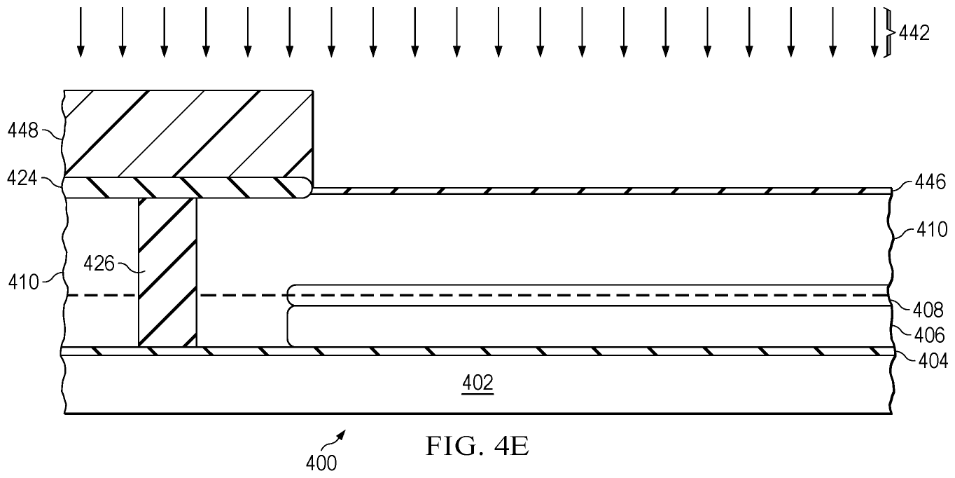

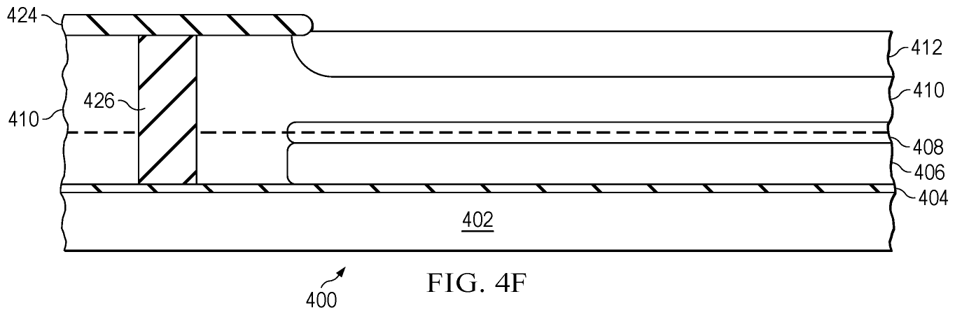

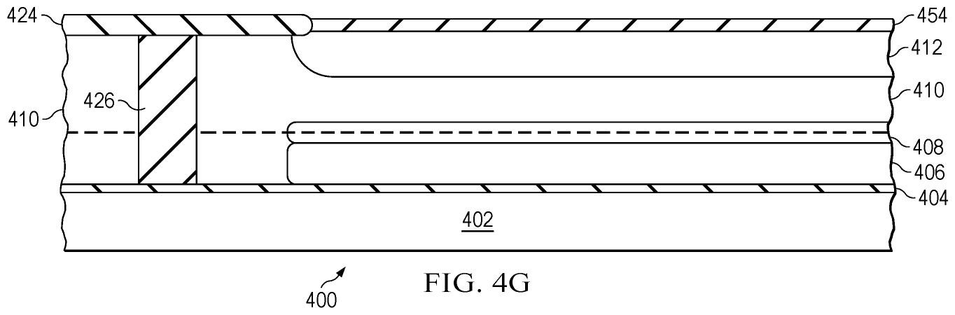

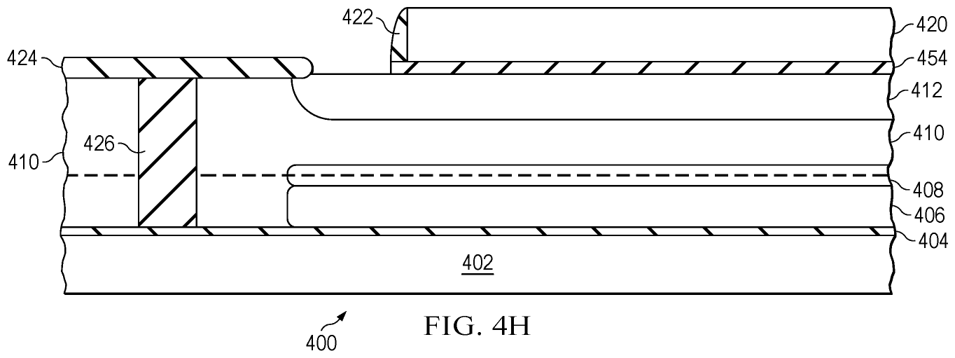

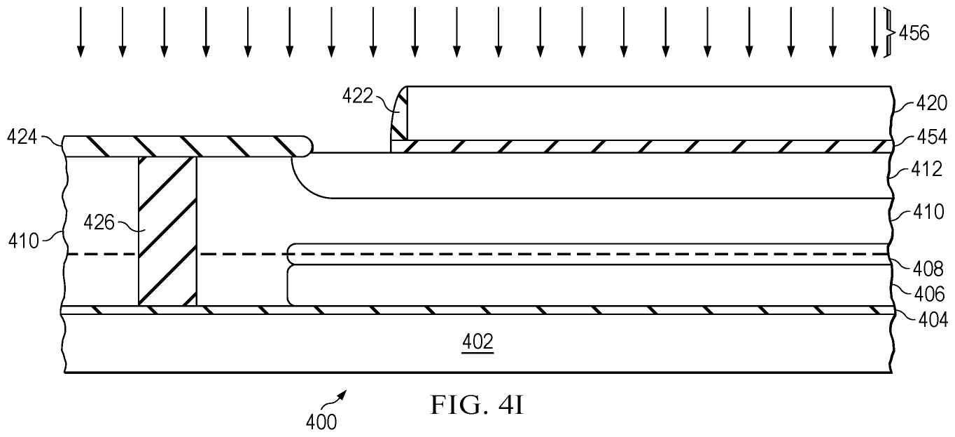

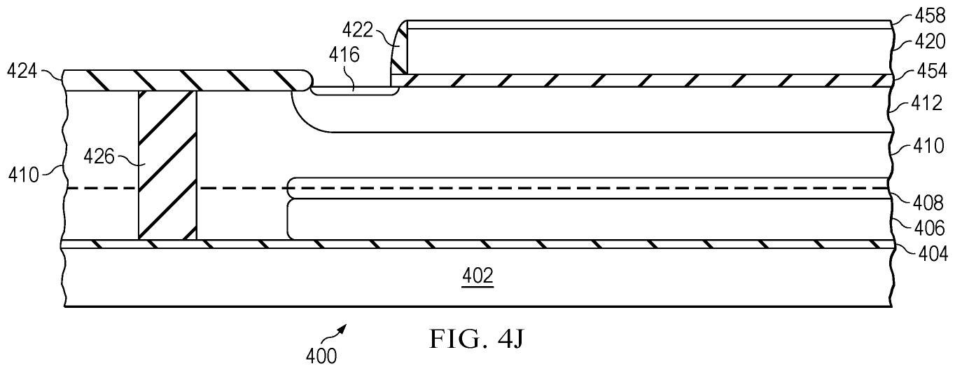

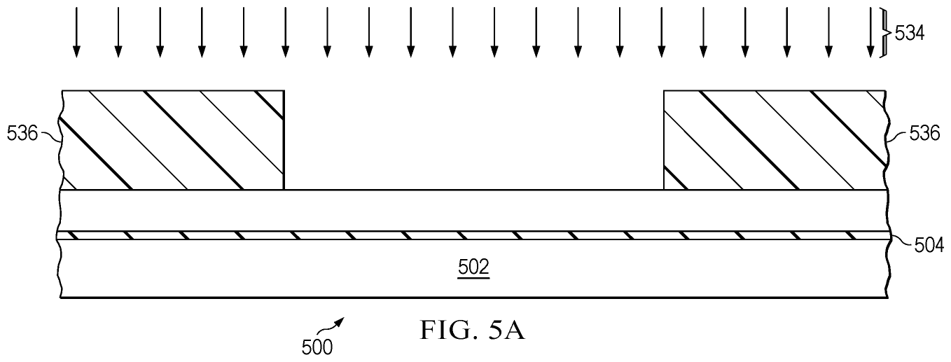

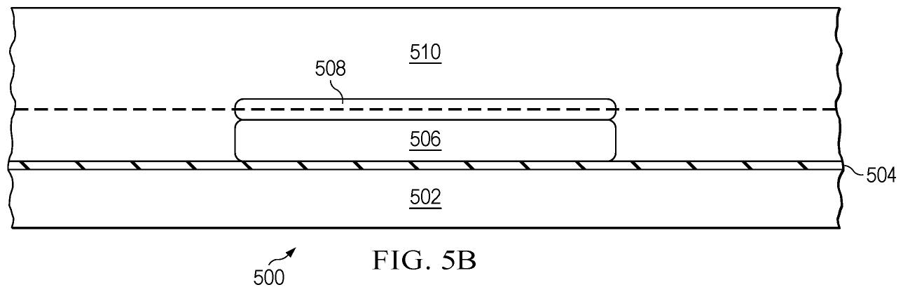

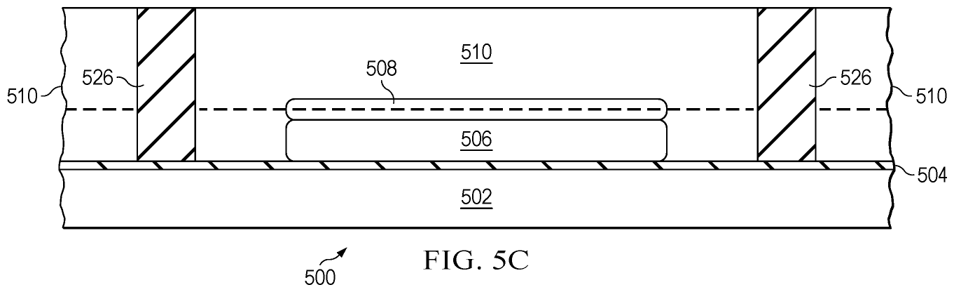

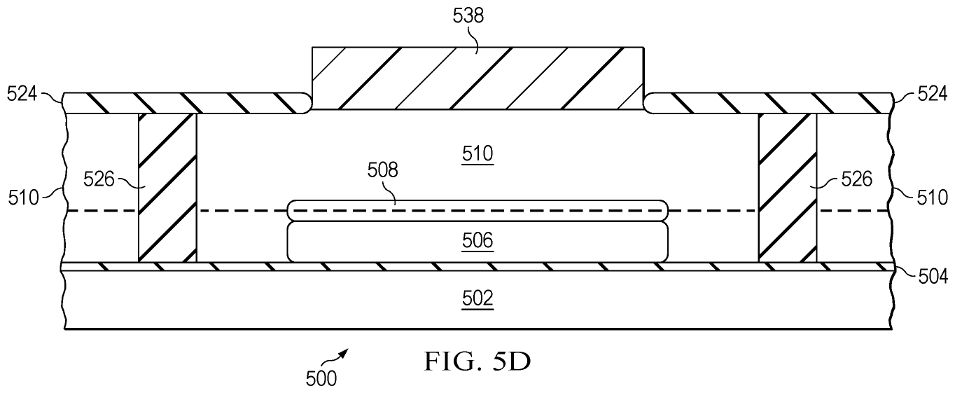

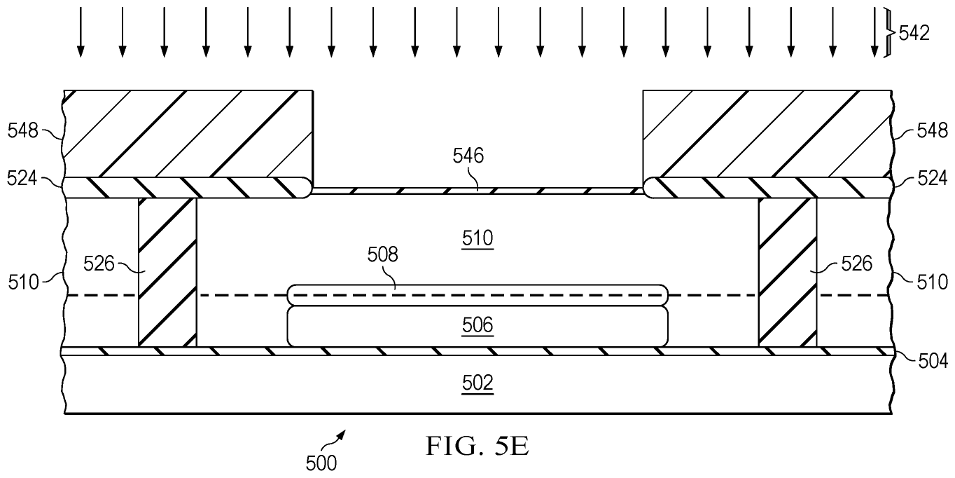

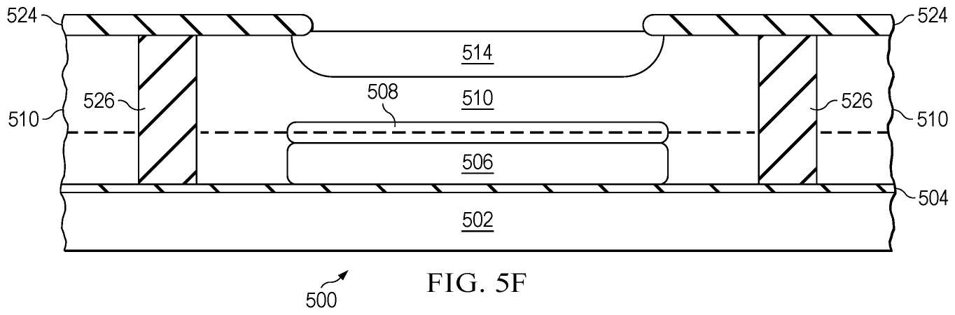

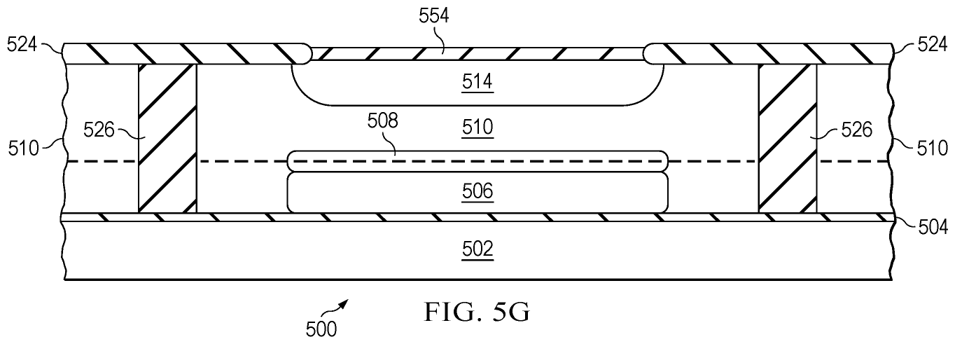

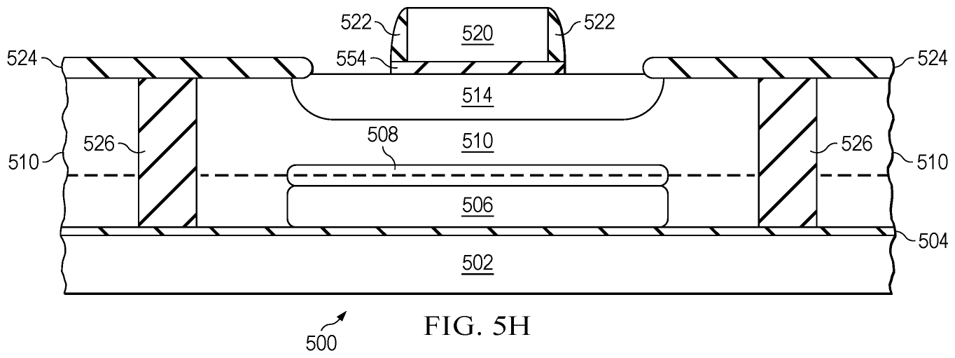

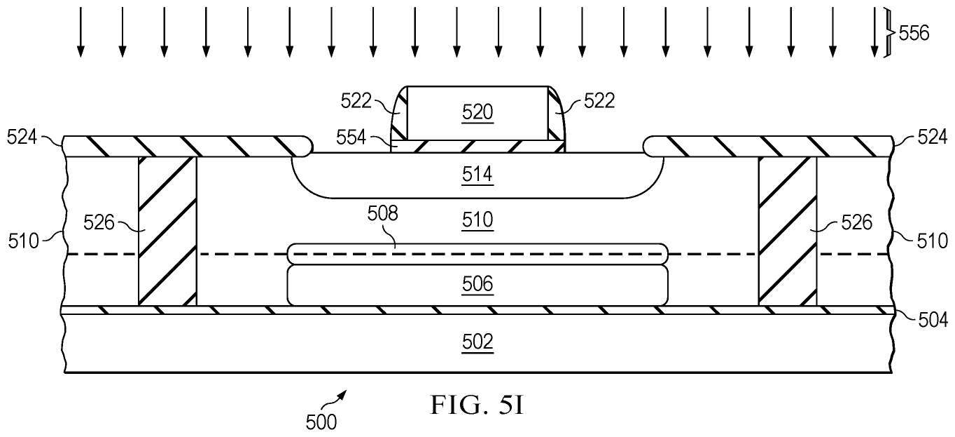

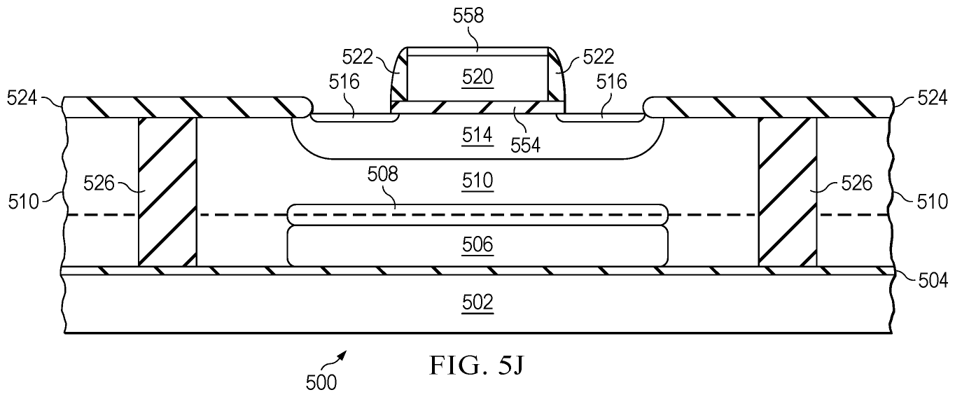

FIGS. 4A-4J (collectively “FIG. 4”) are side views of an example process for fabricating a capacitor 400 consistent with the capacitor 200. FIGS. 5A-5J (collectively “FIG. 5”) are side views of an example process for forming a transistor 500 using the processing steps as illustrated in FIG. 4. Capacitor 400 is structured for a lower operating voltage than capacitor 300. In an example, capacitor 300 may be utilized in a 7 V circuit and capacitor 400 may be utilized in a 5 V circuit. Referring to FIG. 4A, buried oxide layer 404 is formed in substrate 402 by implantation of oxygen into substrate 402. A first step of a two-step implantation 434 (also shown as two-step implantation 534 in FIG. 5A) is implantation of antimony ions having a density of 1×10¹⁵ atoms/cm² at an energy of 140 keV using first mask 432, which forms first buried layer 406 as shown in FIG. 4B. The second step is implantation of phosphorous ions having a density of 1.28×10¹³ and an energy of 90 keV, which forms second buried layer 408 as shown in FIG. 4B. A difference between first buried layer 406 and first buried layer 306 (FIG. 3), and between second buried layer 408 and second buried layer 308 (FIG. 3) is that first buried layer 406 and second buried layer 408 are separated from trench isolation 426 by a distance in the range of 0.3 to 1.5 μm. In this example, they are separated by 0.7 μm. In the higher voltage device, it is more important to avoid electric field concentrations at the corners of first buried layer 306 and second buried layer 308 (FIG. 3). In the lower voltage device, it is more important to avoid stray capacitances involving first buried layer 406 and second buried layer 408.

Referring to FIG. 5A, an implantation of oxygen atoms forms buried oxide layer 504 in substrate 502. In an example, substrate 502 and substrate 402 (FIG. 4) are different portions of the same substrate and the implantation of oxygen atoms in FIG. 5A is the same implantation as illustrated in FIG. 4A. In the example of FIG. 4 and FIG. 5, fabrication processes such as implantation, oxidation, and formation of trench isolation regions that are performed in FIG. 4 are simultaneously performed in FIG. 5. In other examples, these steps might be performed at separate times with appropriate masking.

A first step of a two-step implantation 534 is implantation of antimony ions having a density of 1×10¹⁵ atoms/cm² at an energy of 140 keV using first mask 536 to form first buried layer 506 (sometimes called a transistor buried layer). The second step is implantation of phosphorous ions having a density of 1.28×10¹³ and an energy of 90 keV, which forms second buried layer 508 (also sometimes called a transistor buried layer) as shown in FIG. 5B.

Epitaxial deposition forms epitaxial layer 410 (FIG. 4B) and epitaxial layer 510 (FIG. 5B) to a thickness of about 2 μm. In an example, epitaxial layer 410 and epitaxial layer 510 are lightly doped to an N— doping during the epitaxial deposition process by including dopant bearing gas during the process. As shown in FIG. 4, a portion of second buried layer 408 will diffuse into epitaxial layer 410 during the epitaxial deposition process. Similarly, a portion of second buried layer 508 will diffuse into epitaxial layer 510 during the epitaxial deposition process. Trench isolation 426 (FIG. 4C) and trench isolation 526 (FIG. 5C) are formed by etching a trench from the surface of epitaxial layer 410/510 to buried oxide layer 404/504. An oxide layer (not shown) is formed on the surface of the trench by either deposition or thermal oxidation. As an alternative, other dielectric materials may be used on the walls of the trench. The remainder of trench isolation 426 and trench isolation 526 are then filled with polycrystalline silicon. Although trench isolation 426 and trench isolation 526 are only shown in one or two places in FIG. 4C and FIG. 5C, respectively, in most examples, trench isolation 426 surrounds the area in which capacitor 400 is formed and trench isolation 526 surrounds the area in which transistor 500 is formed. Field oxide 424 also surrounds capacitor 400 in this example. Field oxide 424 is formed by local oxidation of the surface of epitaxial layer 410 using mask 438 or by formation of shallow trenches that are subsequently filled with deposited silicon dioxide, or another suitable dielectric as shown in FIG. 4D. Similarly, field oxide 524 is formed using mask 538 such that field oxide 524 also surrounds transistor 500 in this example and is formed using the same fabrication steps used to form field oxide 424 as shown in FIG. 5D.

Referring to FIG. 4E, an oxidation step, such as an N₂/O₂ ambient at a temperature of 1,270° C. for 15 minutes forms sacrificial gate oxide 446 to a thickness of 600 Å on epitaxial layer 410 where epitaxial layer 410 is not covered by field oxide 424. Similarly, this oxidation step forms sacrificial oxide 546 as shown in FIG. 5E. Second mask 448 and second mask 548 are formed and patterned as shown in FIGS. 4E and 5E, respectively. Second implantation /542 is a chain of implants of phosphorus ions having densities of 1.1×10¹³ ion/cm², 4.1×10¹¹ ion/cm², and 1.9×10¹² ion/cm², and energies of 360 keV, 190 keV, and 80 keV, respectively, to form plate region 412 (sometimes referred to as a capacitor well) as shown in FIG. 4F. A second plate region such as first plate region 312 (FIG. 3) is not needed because of the lower operating voltage of capacitor 400. In addition, to lower the number of dislocations in epitaxial layer 410, plate region 412 does not extend to second buried layer 408. This provides a portion of epitaxial layer 410 that has not been implanted, thus avoiding the crystal dislocations caused by implantation. Avoiding dislocations caused by implantation provides fewer pathways for migration of metals and other contaminants from the bulk of substrate 402 and/or epitaxial layer 410 to the interface of capacitor oxide layer 454 (FIG. 4H) and plate region 412, thus mitigating the chance of failure caused by these metals and other contaminants. After second implantation 442 and its associated anneal, a wet etch removes sacrificial oxide layer 446 and sacrificial gate oxide 546. Second implantation 542 is the same implantation as second implantation 442 in this example, and forms well region 514 as shown in FIG. 5F. First gate oxide 552 is removed by that step.

Referring to FIG. 4G, an oxidation in a steam ambient at a temperature of 850° C. for 110 minutes forms capacitor oxide layer 454 having a thickness of about 125 Å (12.5 nm) on the portion of epitaxial layer 410 (on the surface of plate region 412). This oxidation step also forms second gate oxide 554 as shown in FIG. 5G.

The growth rate of the capacitor oxide layer 454 is determined in part by the dopant concentration in the plate region 412. In particular, because the dopant concentration in the plate region 412 is low relative to the dopant concentration in the second plate region 350 (FIG. 3H) (e.g. about 1/25^{th} or 4%), the capacitor oxide layer 454 generally has a lower growth rate than does the capacitor oxide layer 354. Thus, by virtue of the different dopant concentration the second plate region 350 and the plate region 412, the capacitor oxide layer 354 and the capacitor oxide layer 454 may be simultaneously formed (in a single oxidation step) having different thicknesses. Some baseline devices use two oxidation steps: a first to form a capacitor dielectric for low voltage (e.g. 5 V) capacitors and a partial capacitor dielectric for high voltage (e.g. 7 V) capacitors; and a second to complete the capacitor dielectric for the high voltage capacitors with the low voltage capacitors masked off. Thus, in a capacitor like capacitors 100 and 300, the effects of impurities on the capacitance of the capacitor are mitigated, and the oxide layers 354, 454 and 554 may all be formed in a single oxidation step.

Referring to FIG. 4H and FIG. 5H, chemical vapor deposition forms a polycrystalline silicon layer overall. This polycrystalline silicon layer is patterned to using a mask and etching to form plate 420 and gate 520. The polycrystalline silicon is deposited with a dopant material for conductivity of plate 420 and gate 520. In some examples, before patterning, the polycrystalline layer is implanted with dopant ions to provide additional conductivity. Side wall 422 and sidewalls 522 are optionally formed by deposition of a dielectric that is then anisotropically etched away leaving the side wall 422 and sidewalls 522 and removing the exposed portions of capacitor oxide layer 454 as shown in FIG. 4I and FIG. 5I, respectively.

Third implantation 456 and third implantation 556 are simultaneous implantations of arsenic with a density of 2.53×10¹⁵ ions/cm², and an energy of 100 keV as shown in FIG. 4J and FIG. 5J, respectively. This implantation forms contact 416 and source/drains 516 and shown in FIG. 4K and FIG. 5K, respectively. In addition, third implantation 456 forms doped layer 458 on plate 420 and third implantation 556 forms doped layer 558 on gate 520.

Modifications are possible in the described examples, and other examples are possible, within the scope of the claims.

What is claimed is:

1. An integrated circuit comprising:
a transistor having:
a transistor well extending into a semiconductor substrate having a first dopant concentration;
a gate electrode over the transistor well;
a gate insulating layer between the transistor well and the gate electrode, the gate insulating layer having a first thickness; and
a capacitor having:
a capacitor well extending into the semiconductor substrate having a second dopant concentration greater than the first dopant concentration;
a capacitor electrode over the capacitor well; and
a homogeneous capacitor insulating layer between the capacitor well and the capacitor electrode having a greater thickness than the gate insulating layer.

2. The integrated circuit of claim 1, wherein a thickness of the homogeneous capacitor insulating layer is at least 50% greater than a thickness of the gate insulating layer.

3. The integrated circuit of claim 1, further comprising a trench isolation surrounding the capacitor.

4. The integrated circuit of claim 3, wherein the capacitor well is spaced 2-4 μm from the trench isolation.

5. The integrated circuit of claim 3, wherein the trench isolation includes a dielectric material extending from a surface of the semiconductor substrate.

6. The integrated circuit of claim 5, wherein the trench isolation further includes polycrystalline silicon, the dielectric material separating the polycrystalline silicon from the semiconductor substrate.

7. The integrated circuit of claim 1, wherein the capacitor electrode includes polycrystalline silicon.

8. An integrated circuit comprising:
an epitaxial layer having a first conductivity type over a semiconductor substrate;
a buried layer having the first conductivity type between the epitaxial layer and the substrate;
a first doped region having the first conductivity type and a first dopant concentration extending into the epitaxial layer toward the buried layer;
a second doped region having the first conductivity type and a second greater dopant concentration extending into the first doped region toward the buried layer;
an electrode over the second doped region; and
a dielectric layer between the electrode and the second doped region.

9. The integrated circuit of claim 8, wherein the dopant concentration of the capacitor well is 5×10¹⁸ atoms/cm³.

10. The integrated circuit of claim 8, wherein the epitaxial layer is crystalline silicon.

11. The integrated circuit of claim 8, further comprising a trench isolation surrounding the capacitor.

12. The integrated circuit of claim 11, wherein the capacitor well is spaced 2-4 μm from the trench isolation.

13. The integrated circuit of claim 11, wherein the trench isolation includes a dielectric material extending from the surface of the epitaxial layer to the buried insulating layer.

14. The integrated circuit of claim 8, wherein the capacitor plate is polycrystalline silicon.

15. A method comprising:
forming a buried insulating layer proximate to but not extending to a surface of a substrate having a first conductivity type;
implanting a transistor buried layer in a transistor area of the substrate and a capacitor buried layer in a capacitor area of the substrate, the transistor buried layer and the capacitor buried layer extending to the buried insulating layer and having a second conductivity type opposite the first conductivity type;
epitaxially depositing an epitaxial layer on the surface of the substrate having the first conductivity type;
forming a sinker layer having the second conductivity type extending from the transistor buried layer to a surface of the epitaxial layer in the transistor area;
forming a capacitor well in the capacitor area having the first conductivity type in the epitaxial layer extending to the surface of the epitaxial layer but not extending to the capacitor buried layer;
a first oxidizing of the surface of the epitaxial layer in the transistor area and the capacitor area;
removing oxide formed on the capacitor area formed by the first oxidizing;
a second oxidizing of the surface of the epitaxial layer in the transistor area and the capacitor area;
depositing and patterning a conductive layer on an oxide formed by the second oxidizing, the conductive layer serving as a gate in the transistor area and a capacitor plate in the capacitor area; and
introducing dopant of the first conductivity type into the surface of the epitaxial layer not covered by the gate in the transistor area and the capacitor plate in the capacitor area, the dopant serving as a first source/drain region and a second source/drain region in the transistor area, the first source/drain region and the second source/drain region formed in the sinker layer on opposing sides of the gate, and the dopant serving as a contact region formed in the capacitor well.

16. The method of claim 15, wherein the implanting a transistor buried layer in a transistor area of the substrate and a capacitor buried layer in a capacitor area of the substrate is a two-step implantation.

17. The method of claim 15, wherein the forming a capacitor well is by implantation.

18. The method of claim 15, wherein the conductive layer is polycrystalline silicon.

19. The method of claim 15, wherein the forming a buried insulating layer is by implantation.

20. The method of claim 19, wherein the implantation is implanting oxygen atoms.

21. The method of claim 15, wherein the removing oxide formed on the capacitor area is by plasma etching.
